(19) United States
(12) Patent Application Publication
(10) Pub. No.: US 2007/0194324 A1
(43) Pub. Date: Aug. 23, 2007

(54) Vertical gallium-nitride based light emitting diode

(75) Inventors: Dong Woo Kim, Seoul (KR); Bang Won Oh, Seognam (KR); Jeong Tak Oh, Suwon (KR); Hyung Ky Back, Suwon (KR); Min Ju Kim, Gimhae (KR)

Correspondence Address: MCDERMOTT WILL & EMERY LLP, 600 13TH STREET, N.W., WASHINGTON, DC, 20005-3096, US

(73) Assignee: Samsung Electro-Mechanics Co., Ltd.

(21) Appl. No.: 11/602,286

(22) Filed: Nov. 21, 2006

(30) Foreign Application Priority Data
Nov. 24, 2005 (KR) 10-2005-0112710

(51) Int. Cl. H01L 33/00; H01L 31/12

(52) U.S. Cl. 257/79

(57) ABSTRACT

A vertical GaN-based LED is provided. The vertical GaN-based LED includes: an n-electrode; an n-type GaN layer formed under the n-electrode; an active layer formed under the n-type GaN layer; a p-type GaN layer formed under the active layer, the p-type GaN layer having a first uneven structure formed on a surface that does not contact the active layer; a p-type reflective electrode formed under the p-type GaN layer having the first uneven structure; and a support layer formed under the p-type reflective electrode.

### CROSS-REFERENCE TO RELATED APPLICATIONS

This application claims the benefit of Korean Patent Application No. 2005-112710 filed with the Korean Industrial Property Office on Nov. 24, 2005, the disclosure of which is incorporated herein by reference.

### BACKGROUND OF THE INVENTION

1. Field of the Invention

The present invention relates to a vertical gallium-nitride (GaN)-based light emitting diode (LED), and more particularly, to a vertical GaN-based LED having high external quantum efficiency.

2. Description of the Related Art

Generally, GaN-based LEDs are grown on a sapphire substrate. The sapphire substrate is rigid and electrically nonconductive and has a low thermal conductivity. Therefore, it is difficult to reduce the size of the GaN-based LED for cost-down or improve the optical power and chip characteristics. Particularly, heat dissipation is very important for the LEDs because a high current should be applied to the GaN-based LEDs so as to increase the optical power of the GaN-based LEDs. To solve these problems, a vertical GaN-based LED has been proposed. In the vertical GaN-based LED, the sapphire substrate is removed using a laser lift-off (hereinafter, referred to as LLO) technology.

However, the conventional vertical GaN-based LED has a problem in that photon generated from an active layer is emitted to the outside of the LED. That is, the external quantum efficiency is degraded.

FIG. 1 is a graph for explaining the reduction in external quantum efficiency in a conventional vertical GaN-based LED. Referring to FIG. 1, an incident angle ⊖₁, at which photon is incident from a GaN layer to the air should be less than a critical angle ⊖_{c}, so that photon generated from an active layer can pass through the GaN layer having a refractive index N₁ greater than a refractive index N₂ of the air and then escape into the air.

When an escaping angle ⊖₂ at which the photon escapes into the air is 90°, the critical angle ⊖_{c} is defined as ⊖_{c}=sin⁻¹ (N₂/N₁). When light propagates from the GaN layer to the air having a refractive index of 1, a critical angle is about 23.6°.

When the incident angle ⊖₁ is greater than the critical angel ⊖_{c}, the photon is totally reflected at an interface between the GaN layer and the air and goes back into the LED. Then, the photon is confined inside the LED, so that the external quantum efficiency is greatly reduced.

To solve the reduction in the external quantum efficiency, U.S Patent Publication No. 20030222263 discloses that convex hemispherical patterns are formed on a surface of an n-type GaN layer to reduce an incident angle ⊖₁ of photon incident from the GaN layer to the air below a critical angle ⊖_{c}.

A method for manufacturing a vertical GaN-based LED disclosed in U.S. Patent Publication No. 20030222263 will be described below with reference to FIGS. 2 to 4.

FIGS. 2A to 2C are sectional views illustrating a method of manufacturing the vertical GaN-based LED disclosed in U.S. Patent Publication No. 20030222263, FIGS. 3A to 3C are enlarged sectional views illustrating a method of manufacturing the vertical GaN-based LED, and FIG. 4 is a sectional view of the vertical GaN-based LED manufactured using the method of FIGS. 2A to 2C and FIGS. 3A to 3C.

Referring to FIG. 2A, an LED structure 16 including GaN and a positive electrode (p-electrode) 18 are formed on a sapphire substrate 24, and a first Pd layer 26 and an In layer 28 are formed on the p-electrode 18. Then, a second Pd layer 30 is formed under a silicon substrate 20.

Referring to FIG. 2B, the silicon substrate 20 where the second Pd layer 30 is formed is attached to the p-electrode 18 where the first Pd layer 26 and the In layer 28 are formed.

Referring to FIG. 2C, the sapphire substrate 24 is removed using an LLO process.

Referring to FIG. 3A, photoresist patterns 32 are formed on predetermined portions of a surface of the exposed LED structure 16 (more specifically, a surface of the n-type GaN layer).

Referring to FIG. 3B, the photoresist patterns 32 are formed in a hemispherical shape through a re-flow process.

Referring to FIG. 3C, the surface of the LED structure 16 is etched using an anisotropic etching process, so that it is patterned in a hemispherical shape.

Referring to FIG. 4, a negative electrode (n-electrode) 34 is formed on the LED structure 16. Through these procedures, the vertical GaN-based LED having the LED structure 16 whose surface is patterned is completed.

However, according to the vertical GaN-based LED manufactured using the method disclosed in U.S. Patent Publication No. 20030222263, because the patterns for improving the external quantum efficiency are formed in a convex hemispherical shape on the surface of the LED structure, the surface of the LED structure on which the patterns can be formed is limited. Accordingly, the improvement of the external quantum efficiency that can be achieved by applying the convex hemispherical patterns is insufficient. Therefore, there is a demand for a new method that can maximize the improvement of the external quantum efficiency.

### SUMMARY OF THE INVENTION

An advantage of the present invention is that it provides a vertical GaN-based LED that can increase the light emission efficiency and maximize the improvement of the external quantum efficiency by forming uneven patterns as fine light-scattering structures on the surface of an n-type GaN layer disposed at a light emission side and the surface of a p-type GaN layer disposed at a light reflection side.

Additional aspect and advantages of the present general inventive concept will be set forth in the description which follows and, in part, will be obvious from the description, or may be learned by practice of the general inventive concept.

According to an aspect of the invention, a vertical GaN-based LED includes: an n-electrode; an n-type GaN layer formed under the n-electrode; an active layer formed under the n-type GaN layer; a p-type GaN layer formed under the active layer, the p-type GaN layer having a first uneven structure formed on a surface that does not contact the active layer; a p-type reflective electrode formed under the p-type GaN layer having the first uneven structure; and a support layer formed under the p-type reflective electrode.

According to another aspect of the present invention, the n-type GaN layer has a second uneven structure on a surface that contacts the n-electrode.

According to a further aspect of the present invention, the first and second uneven structures include a regularly uneven structure and an irregularly uneven structure.

According to a still further aspect of the present invention, the regularly uneven structure includes a structure selected from the group consisting of a polygonal structure, a diffraction structure, a mesh structure, and a combination thereof. The diffraction structure and the mesh structure include one or more lines selected from the group consisting of a straight line, a curved line, and a single closed curve.

According to a still further aspect of the present invention, adjacent polygons of the polygonal structure are spaced apart from one another by a distance equal to or greater than wavelength of light emitted from the active layer so as to improve the refraction characteristic of light emitted from the LED.

According to a still further aspect of the present invention, a width between the lines in the diffraction structure and the mesh structure is equal to or greater than wavelength of light emitted from the active layer so as to improve the refraction characteristic of light emitted from the LED.

According to a still further aspect of the present invention, the n-electrode does not overlap the uneven surface of the diffraction structure. If the n-electrode overlaps the diffraction structure, the contact surface of the n-electrode has roughness due to the uneven surface. Consequently, the electrical characteristic is degraded. That is, there occurs a problem that increases the resistance of a current flow introduced through the n-electrode to the n-type GaN layer.

According to a still further aspect of the present invention, the n-electrode is located at the center portion of the n-type GaN layer in order for the uniform distribution of a current that is transferred through the n-electrode to the n-type GaN layer.

According to a still further aspect of the present invention, the vertical GaN-based LED further includes an adhesive layer formed at an interface between the p-type reflective electrode and the support layer so as to adhere them more tightly.

According to the present invention, the uneven structure for improving the external quantum efficiency is provided at the GaN layer of the light emission side and the GaN layer of the light reflection side, that is, on the surface of the n-type GaN layer contacting the n-electrode and the surface of the p-type GaN layer contacting the p-type reflective electrode. Therefore, the external quantum efficiency of the LED can be maximized.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram for explaining the reduction of an external quantum efficiency in a conventional vertical GaN-based LED;

FIGS. 2A to 2C are sectional views illustrating a method of manufacturing a vertical GaN-based LED disclosed in U.S. Patent Publication No. 20030222263;

FIGS. 3A to 3C are enlarged sectional views illustrating a method of manufacturing the vertical GaN-based LED of FIGS. 2A to 2C;

FIG. 4 is a sectional view of the vertical GaN-based LED manufactured using the method of FIGS. 2A to 2C and FIGS. 3A to 3C;

FIG. 5 is a perspective view of a vertical GaN-based LED according to an embodiment of the present invention;

FIG. 6 is a plan view illustrating the arrangement of uneven patterns in the vertical GaN-based LED of FIG. 5;

FIG. 7 is a plan view illustrating the arrangement of first uneven patterns according to a first modification of the present invention;

FIG. 8 is a plan view illustrating the arrangement of first uneven patterns according to a second modification of the present invention;

FIG. 9 is a plan view illustrating the arrangement of first uneven patterns according to a third modification of the present invention; and

FIG. 10 is a plan view illustrating the arrangement of first uneven patterns according to a fourth modification of the present invention.

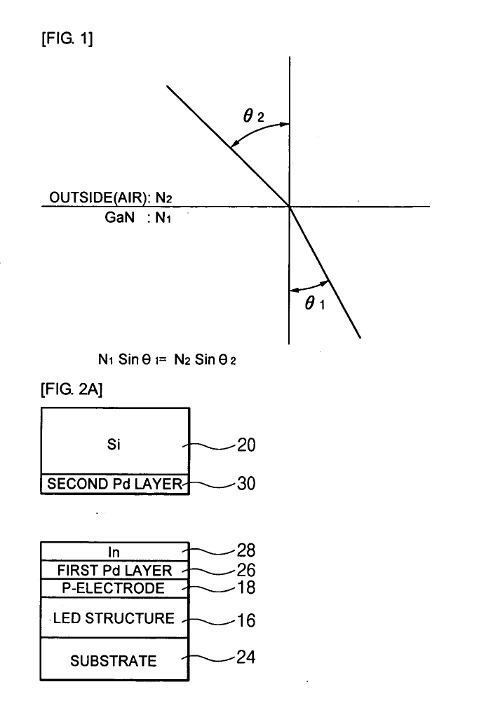

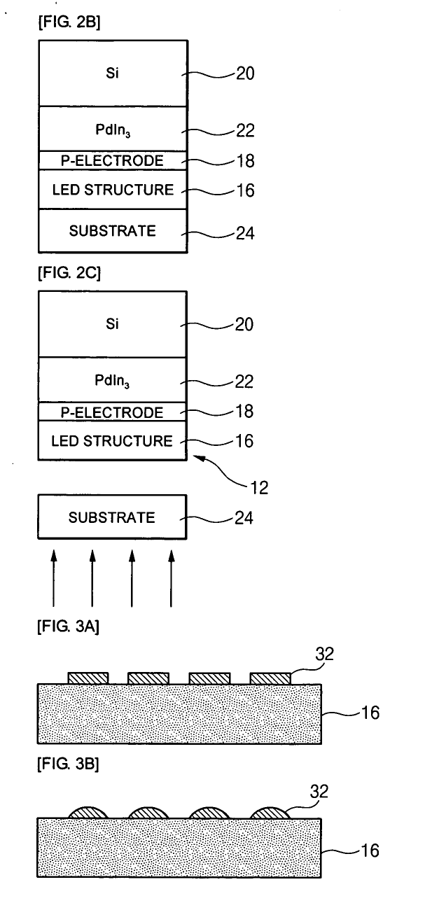

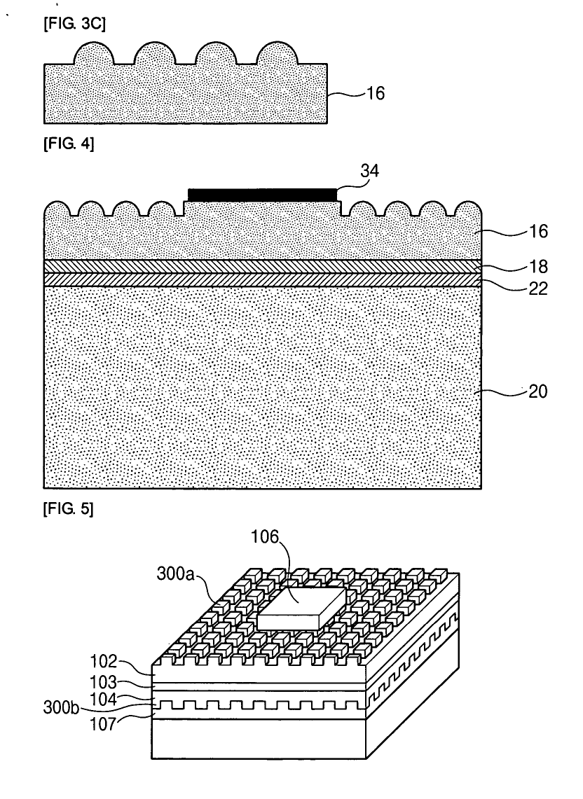

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

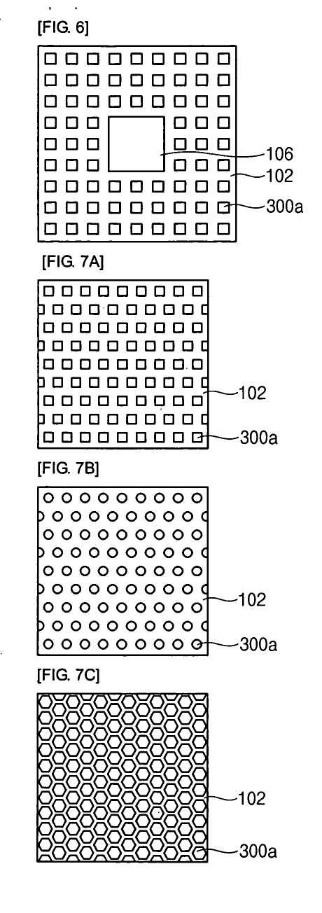

Hereinafter, a vertical GaN-based LED according to the embodiments of the present invention will be described in detail with reference to FIGS. 5 to 10.

First, a vertical GaN-based LED according to an embodiment of the present invention will be described below with reference to FIGS. 5 and 6.

FIG. 5 is a perspective view of a vertical GaN-based LED according to an embodiment of the present invention, and FIG. 6 is a plan view illustrating the arrangement of uneven patterns in the vertical GaN-based LED of FIG. 5.

Referring to FIGS. 5 and 6, an n-electrode 106 is formed on the uppermost surface of the vertical GaN-based LED. The n-electrode 106 may be formed of Ti/Al.

An n-type GaN layer 102 is formed under the n-electrode 106. The n-type GaN layer 102 may be an n-doped GaN layer or an n-doped GaN/AlGaN layer.

Although the n-electrode 106 may be located at any position of the n-type GaN layer 102, it is preferable that the n-electrode 106 is located at the center portion of the n-type GaN layer 102 in order to uniformize the distribution of currents that are transferred through the n-electrode 106 to the n-type GaN layer 102.

In this embodiment, as illustrated in FIG. 5, first uneven patterns 300a are formed in the surface of the n-type GaN layer 102 contacting the n-electrode 106, that is, the surface of the GaN layer disposed at the light emission side. That is, some portions of the surface of the n-type GaN layer 102 are formed to protrude in a predetermined shape to form the first uneven patterns 300a.

The first uneven patterns 300a improve the scattering characteristic of photons generated from an active layer, which will be described later, and efficiently emit the photons to the outside. The first uneven patterns 300a may be regular or irregular.

When the first uneven patterns 300a have the regular structure, it is preferable that the regular structure is selected from the group consisting of a polygonal structure, a diffraction structure, a mesh structure, and a combination thereof. In addition, the diffraction structure and the mesh structure include one or more lines. The lines may be selected from the group consisting of a straight line, a curved line, and a single closed curve.

Although the lines of FIGS. 5 and 6 have a rectangular shape, the present invention is not limited to the rectangular shape. That is, the lines can also have a hemispherical shape, a triangular shape, and so on.

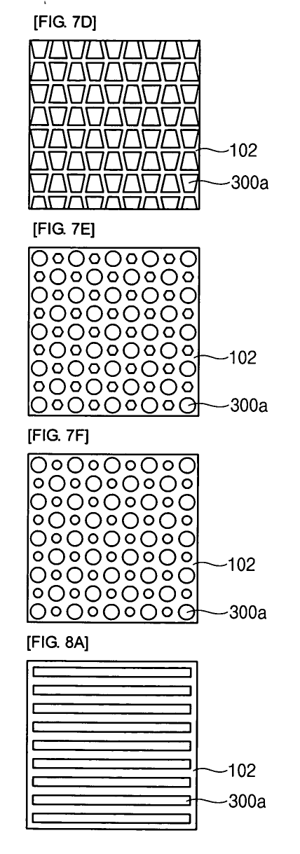

Hereinafter, the structures of the first uneven patterns 300a will be described below in detail with reference to FIGS. 7 to 10.

Modification 1

The first uneven patterns according to a first modification of the present invention will be described below in detail with reference to FIG. 7.

FIG. 7 is a plan view illustrating the arrangement of the first uneven patterns according to the first modification of the present invention.

Referring to FIG. 7, the first uneven patterns 300a have a polygonal structure in which one or more polygons are periodically arranged on the surface of the n-type GaN layer 102 contacting the n-electrode 106 and are spaced apart from one another by a predetermined distance.

Specifically, it is preferable that the adjacent polygons are spaced apart at a distance equal to or greater than the wavelength of light emitted from the active layer so as to improve the refraction characteristic of light emitted from the LED. For example, when blue light is emitted from the active layer 103, the lines are spaced apart by more than about 400-450 nm because the wavelength of the blue light ranges from about 400 nm to about 450 nm.

In this manner, the light emitted from the active layer 103 to the outside can have excellent refraction characteristic. Therefore, it is possible to minimize an amount of light that is irregularly reflected within the LED due to the low refraction of light.

Moreover, the polygons for the first uneven patterns 300a having the polygonal structure may be circles, rectangles, or hexagons. That is, as illustrated in FIG. 7, the first uneven patterns 300a can have various polygonal structures.

Modification 2

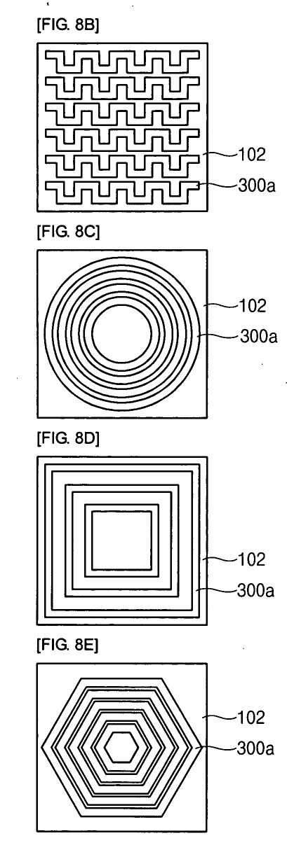

The first uneven patterns according to a second modification of the present invention will be described below in detail with reference to FIG. 8.

FIG. 8 is a plan view illustrating the arrangement of the first uneven patterns according to the second modification of the present invention.

Referring to FIG. 8, the first uneven patterns 300a have a diffraction structure in which one or more lines are periodically arranged in the same direction and are spaced apart from one another by a predetermined distance. Specifically, it is preferable that the adjacent lines are spaced apart by a distance equal to or greater than the wavelength of light emitted from the active layer so as to improve the refraction characteristic of light emitted from the LED.

Moreover, the lines composing the first uneven patterns 300a having the diffraction structure may be straight lines, curved lines, or single closed curves. That is, as illustrated in FIG. 8, the first uneven patterns 300a can have various diffraction structures.

Modification 3

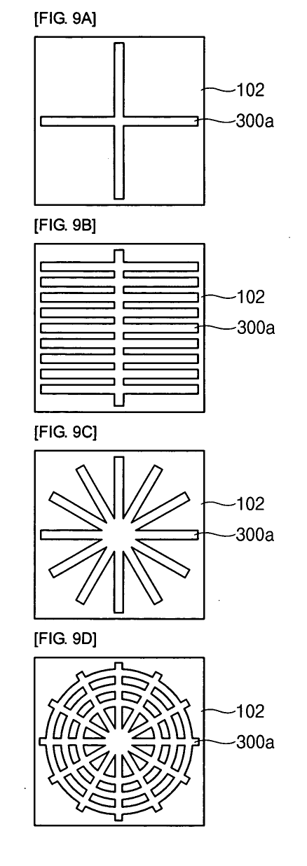

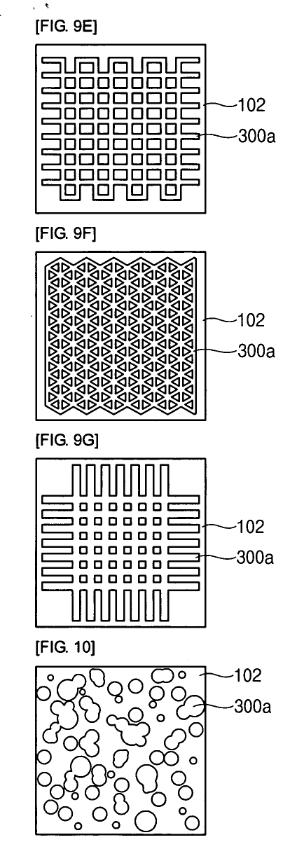

The first uneven patterns according to a third modification of the present invention will be described below in detail with reference to FIG. 9.

FIG. 9 is a plan view illustrating the arrangement of the first uneven patterns according to the third modification of the present invention.

Referring to FIG. 9, the first uneven patterns 300a have a mesh structure in which two or more lines are intersected at one or more points. Like the second modification of the present invention, the lines composing the first uneven patterns 300a having the mesh structure may be straight lines, curved lines, or single closed curves.

### Embodiment 4

The first uneven patterns according to a fourth modification of the present invention will be described below in detail with reference to FIG. 10.

FIG. 10 is a plan view illustrating the arrangement of the first uneven patterns according to the fourth modification of the present invention.

Referring to FIG. 10, the first uneven patterns 300a are irregularly arranged. The first uneven patterns 300a may be polygons, curved lines, or single closed curves.

Although not shown, it is more preferable that the first uneven patterns 300a are formed on the surface of the n-type GaN layer 102 that does not overlap the n-electrode 106. If the n-electrode 106 is formed at the position overlapping the first uneven patterns 300a, the contact surface of the n-electrode 106 has roughness due to the first uneven patterns 300a. Thus, the resistance of a current flow introduced through the n-electrode 106 to the n-type GaN layer 102 will be increased, resulting in the degradation of electrical characteristics.

Meanwhile, an active layer 103 and a p-type GaN layer 104 are sequentially formed under the n-type GaN layer 102. The p-type GaN layer 104 may be a p-doped GaN layer or a p-doped GaN/AlGaN layer. The active layer 103 may have a multi-quantum well structure formed of InGaN/GaN layer.

A p-type reflective electrode 107 is formed under the p-type GaN layer 104. Although not shown, it is preferable that an adhesive layer is further provided at an interface between the p-type GaN layer 104 and the p-type reflective layer 107 so as to adhere them more tightly. Because the adhesive layer can increase the effective carrier concentration of the p-type GaN layer, it is preferable that the adhesive layer is formed of metal having good reaction with components other than nitrogen among compounds of the p-type GaN layer.

More specifically, like the first uneven patterns (300a in FIGS. 6 to 9) formed on the surface of the n-type GaN layer 104 contacting the n-electrode 106, second uneven patterns 300b are formed on the surface of the p-type GaN layer 104 contacting the p-type reflective electrode 107. That is, some portions of the surface of the p-type GaN layer 104 are formed to protrude in a predetermined shape to form the second uneven patterns 300b. Like the first uneven patterns 300a, the second uneven patterns 300b improve the scattering characteristic of photons generated from the active layer 103. Because the photons are efficiently emitted toward the light emission side, the external quantum efficiency can be remarkably improved.

A support layer 100 is disposed under the p-type reflective electrode 107 to support the vertical GaN-based LED. An adhesive layer (not shown) may also be provided at an interface between the p-type reflective electrode 107 and the support layer 100 so as to adhere them more tightly.

In the above-described vertical GaN-based LED, the uneven patterns are formed on both the surface of the n-type GaN layer contacting the n-electrode and the surface of the p-type GaN layer contacting the p-type reflective electrode. However, the uneven patterns formed on the surface of the n-type GaN layer can be omitted according to the characteristics and manufacturing processes of the vertical GaN-based LED.

As described above, the scattering characteristic of the photons generated from the active layer can be improved by forming the uneven patterns on the surface of the GaN layer disposed at the light emission side and the surface of the GaN layer disposed at the light reflection side. Consequently, the external quantum efficiency can be maximized.

The remarkably improved external quantum efficiency of the vertical GaN-based LED can contribute to the quality improvement of the vertical GaN-based LEDs and products using the same.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A vertical gallium-nitride (GaN)-based light emitting diode (LED) comprising:
an n-electrode;
an n-type GaN layer formed under the n-electrode;
an active layer formed under the n-type GaN layer;
a p-type GaN layer formed under the active layer, the p-type GaN layer having a first uneven structure formed on a surface that does not contact the active layer;
a p-type reflective electrode formed under the p-type GaN layer having the first uneven structure; and
a support layer formed under the p-type reflective electrode.

2. The vertical GaN-based LED according to claim 1,
wherein the n-type GaN layer has a second uneven structure on a surface that contacts the n-electrode.

3. The vertical GaN-based LED according to claim 2,
wherein the first and second uneven structures includes a regularly uneven structure and an irregularly uneven structure.

4. The vertical GaN-based LED according to claim 3,
wherein the regularly uneven structure includes a structure selected from the group consisting of a polygonal structure, a diffraction structure, a mesh structure, and a combination thereof.

5. The vertical GaN-based LED according to claim 4,
wherein adjacent polygons of the polygonal structure are spaced apart from one another by a distance equal to or greater than wavelength of light emitted from the active layer.

6. The vertical GaN-based LED according to claim 4,
wherein the diffraction structure and the mesh structure include one or more lines selected from the group consisting of a straight line, a curved line, and a single closed curve.

7. The vertical GaN-based LED according to claim 6,
wherein a width between the lines in the diffraction structure and the mesh structure is equal to or greater than wavelength of light emitted from the active layer.

8. The vertical GaN-based LED according to claim 2,
wherein the n-electrode does not overlap the second uneven structure.

9. The vertical GaN-based LED according to claim 1,
wherein the n-electrode is located at the center portion of the n-type GaN layer.

10. The vertical GaN-based LED according to claim 1, further comprising:
an adhesive layer formed at an interface between the p-type reflective electrode and the support layer.
